(19) United States
(12) Patent Application Publication
(10) Pub. No.: US 2006/0237829 A1
(43) Pub. Date: Oct. 26, 2006

(54) Method and system for a semiconductor package with an air vent

(76) Inventor: Eiichi Hosomi, Austin, TX (US)

Correspondence Address: SPRINKLE IP LAW GROUP, 1301 W. 25TH STREET, SUITE 408, AUSTIN, TX, 78705, US

(21) Appl. No.: 11/114,808

(22) Filed: Apr. 26, 2005

(51) Int. Cl. H01L 23/02

(52) U.S. Cl. 257/678

(57) ABSTRACT

Systems and methods for a structure for semiconductor packages where the effects that features on the package substrate have on the impedance of signal traces within the semiconductor package is substantially reduced. These systems and methods may allow a feature, or multiple features, to be placed anywhere on the semiconductor package while still minimizing the effect of these features on the impedance of signal traces within the package substrate of the semiconductor package that are beneath these features. In particular, these systems and methods may be useful in a semiconductor package with an air vent, such that the placement of an air vent or air vents in the semiconductor package does not affect signal traces beneath the air vent. Thus, a design rule applicable to signal traces in the remainder of that region may be applied to any signal traces that happen to exist beneath the air vent.

### TECHNICAL FIELD OF THE INVENTION

The invention relates in general to heat dissipation in semiconductor devices, and more particularly, to methods and systems for dissipating heat in a semiconductor package with reduced effects on the impedance of signal traces in the semiconductor package.

### BACKGROUND OF THE INVENTION

With the advent of the computer age, electronic systems have become a staple of modern life. Part and parcel with this spread of technology comes an ever greater drive for more functionality from these electronic systems. A microcosm of this quest for increased functionality is the size and capacity of various semiconductor devices. From the 8 bit microprocessor of the original Apple I, through the 16 bit processors of the original IBM PC AT, to the current day, the processing power of semiconductors has grown while the size of these semiconductors has consistently been reduce. In fact, Moore's law recites that the number of transistors on a given size piece of silicon will double every 18 months.

As semiconductors have evolved into these complex systems utilized in powerful computing architectures, almost universally, the frequency at which these semiconductors devices operate has been increasing. Commensurate with the increase in frequency, the power requirements for these semiconductors have also been increasing. In fact, the higher the clock frequency at which a semiconductor device operates, the greater that semiconductor device's power consumption (all other aspects being equal).

The high frequency and power consumption of modern semiconductor devices, however, has given rise to another problem, heat. The high operating frequencies and power consumption of these semiconductor devices produces a large amount of heat. This heat may cause the semiconductor device to function less efficiently, or in some extreme cases may cause the failure of the semiconductor device or components of a system in close proximity to the semiconductor device. Typically, to remedy this, some form of mechanical cooling aid is attached to the semiconductor package. One type of mechanical cooling aid is a metal plate known as a “heat spreader” or “lid” which is attached to the semiconductor package. This lid can be a one body type, or consist of multiple parts like a stiffener ring and cover plate.

Turning briefly to FIG. 1, one example of a semiconductor package 100 with a heat spreader or lid is depicted. Die 110 containing an integrated circuit or semiconductor device, such as a microprocessor, is coupled to package substrate 120. Adhesive 140, 150 couples lid 160 to substrate 120. Lid 160 may serve to dissipate the heat produced by die 100. In the embodiment depicted, lid 160 is a one-body type lid which is made of a metal of high-thermal conductivity such as copper or a copper alloy. As die 110 and substrate 120 are usually composed of different materials, adhesive 140 and adhesive 150 may be specifically designed to achieve better thermal dissipation between the respective components which they couple. Thus, adhesive 140 and adhesive 150 may be of different types, with adhesive 140 used to fix die 110 to lid 160 designed to provide better thermal conductivity between die 110 and lid 160, while adhesive 150 used to fix substrate 120 to lid 160 is designed to provide better thermal conductivity between substrate 120 and lid 160.

Typically, package substrate 120, with which die 110 is packaged, is made of organic material (such as epoxy resin). Package substrate 120 may be fabricated using build-up technology, which enables higher wiring capability by having fine-line build-up layer(s) on both sides of a coarser core substrate. However, for high speed signal traces it is desirable to keep the impedance of these signal traces substantially constant throughout the areas of substrate 120 where these signal traces pass. However, adhesive 150 may change the impedance of signal traces that pass through the area of package substrate 120 on which adhesive 150 is present relative to the impedance of these signal traces in areas of package substrate 120 where adhesive is not present.

This problem may be illustrated more clearly with respect to the depiction of the embodiment of a semiconductor device presented in FIGS. 2A, 2B and 2C. FIG. 2A presents an overhead view of semiconductor package 200. Note that while a lid is present on semiconductor package 200 the lid is not depicted in FIG. 2A for illustrative purposes. Signal traces 212, present in package substrate 220 or in solder resist on package substrate 220, serve to couple die 210 to a variety of signals or power sources as is known in the art. Signal traces 212 travel from die 210 to a coupling device such as a BGA ball. Consequently, signal traces 212 travel through two distinct regions 240, 250; region 240 where adhesive 260 for coupling a lid (not shown) to package substrate 220 is present and region 250 where adhesive 260 is not present.

Cross sections of portions of these two regions 240, 250 are illustrated in more detail in FIGS. 2B and 2C. FIG. 2B depicts a cross-sectional view of semiconductor package 220 in region 250 while FIG. 2C depicts a cross sectional view of semiconductor package 220 in region 240. Typically, signal traces 212 are present on package substrate 220 in solder resist. In region 240, adhesive 260 is present and serves to couple lid 270 to package substrate 220. As adhesive 260 may have a high dielectric constant the impedance of signal traces in regions 240 and 250 may be substantially different. The differing impedance of signal traces 212 in regions 240 and 250 may lead to a degradation of the integrity of signals traveling on signal traces 212. Typically, to remedy this problem the design of traces in the semiconductor package (e.g. width of signal traces 212 and space between traces 212 etc.) can be optimized to keep the impedance of signal traces 212 substantially constant throughout both regions 240 and 250.

Utilizing a lid on a semiconductor package, however, may present other problems as well. Namely, it is usually necessary to make an air vent in the lid structure so that expanding air can escape through the air vent when the semiconductor package undergoes a reflow process such as those for attaching ball grid array (BGA) balls to the semiconductor package or during assembly of a printed circuit board with the semiconductor package.

An air vent of this type may be made in a variety of different ways. One methodology involves drilling a hole in the lid structure of a semiconductor package. This solution may be problematic, as lid thicknesses tend to increase in relation to the speed and power consumption of semiconductors. Another methodology of forming an air vent in a semiconductor package is to form an air vent in the adhesive used to attach a lid structure to the semiconductor package. This solution however, may present similar problems to those discussed above with respect to FIGS. 2A, 2B and 2C. In other words, the air vent may affect the impedance of signal traces below the air vent differently than the surrounding adhesive, making it inordinately difficult to design signal traces suitable for use in regions of semiconductor package covered by adhesive where an air vent hole may be formed.

Thus, a need exists for a semiconductor package design where the effects of adhesives, air vent holes and other features on the package substrate on the impedance of signal traces within the semiconductor package are substantially reduced.

### SUMMARY OF THE INVENTION

Systems and methods for a structure of a semiconductor package are presented. In these semiconductor packages the effects that features on the package substrate have on the impedance of signal traces within the semiconductor package is substantially reduced. These systems and methods may allow a feature, or multiple features, to be placed substantially anywhere on the semiconductor package while still minimizing the effect of these features on the impedance of signal traces within the package substrate of the semiconductor package that are beneath these features. In particular, these systems and methods may be useful in a semiconductor package with an air vent, such that the placement of an air vent or air vents in the semiconductor package does not affect signal traces beneath the air vent. In one embodiment, a design rule applicable to signal traces in the remainder of that region may be applied to any signal traces that happen to exist beneath the air vent.

In one embodiment, an air vent hole is formed in the adhesive used to couple a lid to the semiconductor package. None of the signal traces in the semiconductor package are routed beneath this air vent hole.

In another embodiment, a conductive plane is routed beneath the air vent hole.

In yet another embodiment, some of the signal traces are routed beneath the air hole beneath the conductive plane.

Embodiments of the present invention provide the technical advantage that they alleviate or substantially reduce the effect that an air vent hole in a semiconductor package has on the impedance of signal traces in the semiconductor package. Thus, designing or implementing signal traces which maintain substantially similar impedances throughout may be markedly easier.

These, and other, aspects of the invention will be better appreciated and understood when considered in conjunction with the following description and the accompanying drawings. The following description, while indicating various embodiments of the invention and numerous specific details thereof, is given by way of illustration and not of limitation. Many substitutions, modifications, additions or rearrangements may be made within the scope of the invention, and the invention includes all such substitutions, modifications, additions or rearrangements.

### BRIEF DESCRIPTION OF THE DRAWINGS

The drawings accompanying and forming part of this specification are included to depict certain aspects of the invention. A clearer impression of the invention, and of the components and operation of systems provided with the invention, will become more readily apparent by referring to the exemplary, and therefore nonlimiting, embodiments illustrated in the drawings, wherein identical reference numerals designate the same components. Note that the features illustrated in the drawings are not necessarily drawn to scale.

FIG. 1 depicts one embodiment of a prior art semiconductor package with a lid.

FIG. 2A depicts one embodiment of a prior art semiconductor package.

FIGS. 2B and 2C depict partial cross-sectional views of the semiconductor package of FIG. 2A.

FIG. 3 depicts one embodiment of a semiconductor package with a lid and an air vent hole.

FIG. 4 depicts one embodiment of a semiconductor package.

FIG. 5A depicts a cross-sectional view of one embodiment of a semiconductor package.

FIG. 5B depicts a cross-sectional view of one embodiment of a semiconductor package.

FIG. 5C depicts a cross-sectional view of one embodiment of a semiconductor package.

FIG. 6A depicts one embodiment of the placement of an air vent hole in a semiconductor package.

FIG. 6B depicts one embodiment of the placement of an air vent hole in a semiconductor package.

FIG. 6C depicts one embodiment of the placement of an air vent hole in a semiconductor package.

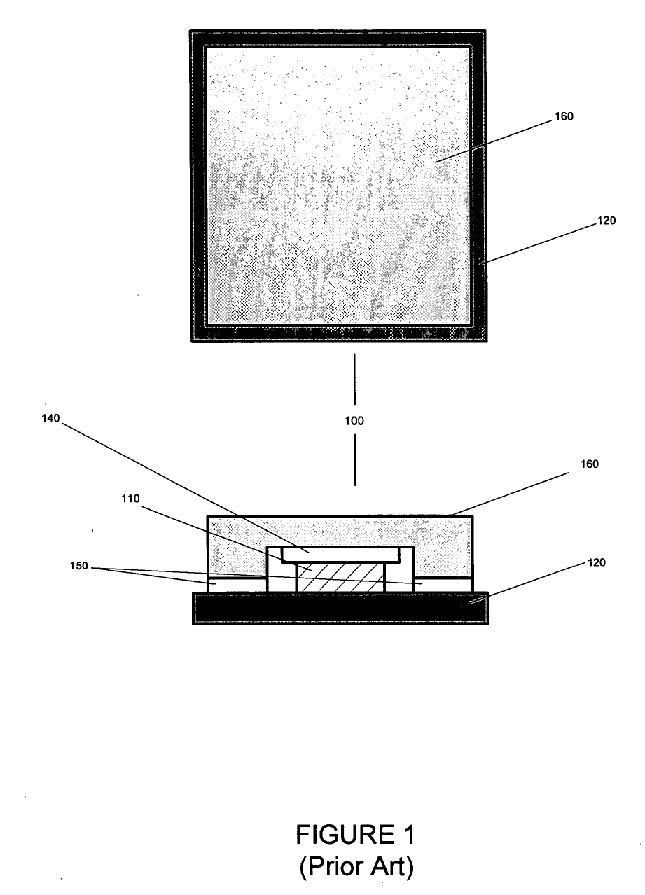

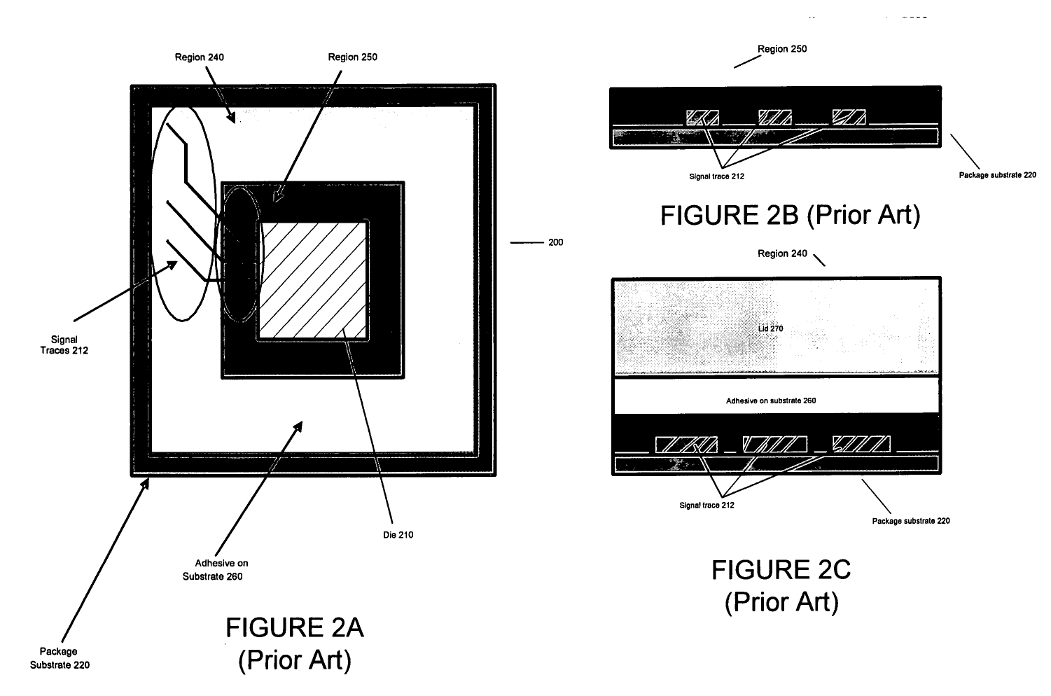

### DESCRIPTION OF PREFERRED EMBODIMENTS

The invention and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the invention in detail. Skilled artisans should understand, however, that the detailed description and the specific examples, while disclosing preferred embodiments of the invention, are given by way of illustration only and not by way of limitation. Various substitutions, modifications, additions or rearrangements within the scope of the underlying inventive concept(s) will become apparent to those skilled in the art after reading this disclosure.

Reference is now made in detail to the exemplary embodiments of the invention, examples of which are illustrated in the accompanying drawings. Wherever possible, the same reference numbers will be used throughout the drawings to refer to the same or like parts (elements).

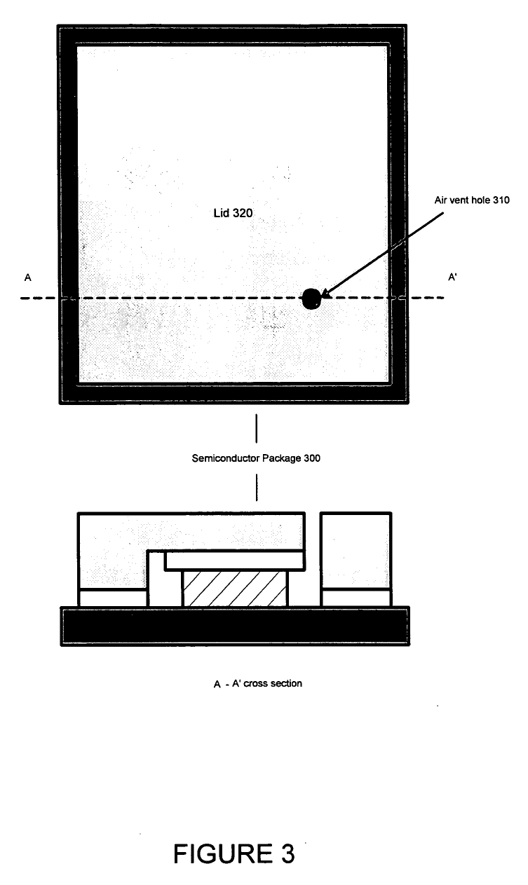

As mentioned above, the formation of an air vent hole in a semiconductor package may present problems for designers of the semiconductor package. One embodiment of an air vent in a semiconductor package is illustrated in FIG. 3. Air vent hole 310 may be drilled in lid 320 of semiconductor package 300. Thus, expanding air can escape from air vent hole 310 during any reflow process after lid 320 is mounted to semiconductor package 300. However, as power consumption and frequency of semiconductors increases the heat dissipation mechanisms utilized must achieve better thermal dissipation. Consequently, in many semiconductor packages the thickness of the lid utilized is increasing to achieve better thermal dissipation in the lateral direction. As the thickness of the lids utilized in conjunction with semiconductor packages increases it becomes increasingly more difficult to make air vent holes in these lids.

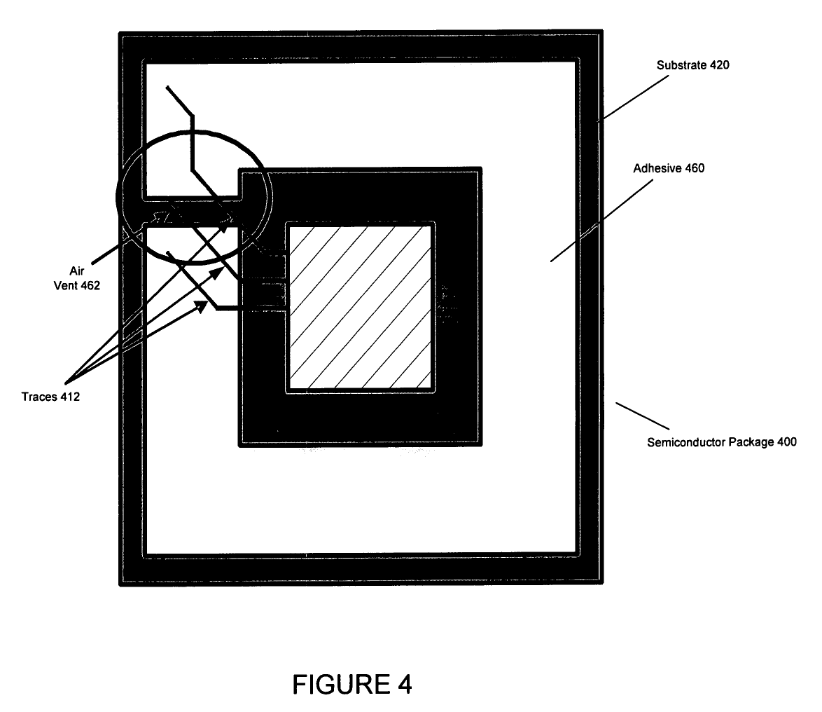

There are, however, other ways to make air vent holes in a semiconductor package. FIG. 4 depicts a partial cross-sectional view of one embodiment of an air hole vent formed in the adhesive on package substrate 420 of semiconductor package 400. Semiconductor package 400 has a lid (not shown) which is coupled to package substrate 420 by adhesive 460. Air vent hole 462 is formed in adhesive 460. Adhesive 460 may be a film type adhesive or a liquid type adhesive. If adhesive 460 is a film type adhesive, air vent hole 462 may be punched in adhesive 460 before adhesive 460 is placed on package substrate 420. If adhesive 460 is a liquid type adhesive it may be screen-printed or dispensed on package substrate 420 such that air vent hole 462 is formed. Thus, air can escape from air vent hole 462 during a reflow process involving semiconductor package 400.

However, as can be seen, the forming of air vent hole 462 in adhesive 460 raises the same issues discussed above. If the air vent hole is placed over signal traces 412 the impedance of signal traces 412 over which the air vent hole is formed will have different impedance from those signal traces 412 over which adhesive 460 lies. Consequently, it may be necessary to design signal traces 412 in semiconductor package 400 (e.g. width of signal traces 412 and space between traces 412) to account for air vent hole 462 such that the impedance of signal traces 412 are substantially constant throughout the their length.

However, the resolution or tolerances of the formation process of air vent hole 462 may be very large relative to signal traces 412, and may be on the order of 1 millimeter or greater. Thus, it may be extremely difficult to create a semiconductor package, or signal trace, design which can compensate for air vent hole 462, as the precise size of air vent hole 462 cannot be determined before the formation process.

Attention is now directed to systems and methods for a structure of a semiconductor package where the effects that features on the package substrate have on the impedance of signal traces within the semiconductor package is substantially reduced. These systems and methods may allow a feature, or multiple features, to be placed anywhere on the semiconductor package while still minimizing the effect of these features on the impedance of signal traces within the package substrate of the semiconductor package that are beneath these features. In particular, these systems and methods may be useful in a semiconductor package with an air vent, such that the placement of an air vent or air vents in the semiconductor package does not affect signal traces beneath the air vent. Thus, a design rule applicable to signal traces in the remainder of that region may be applied to any signal traces that happen to exist beneath the air vent.

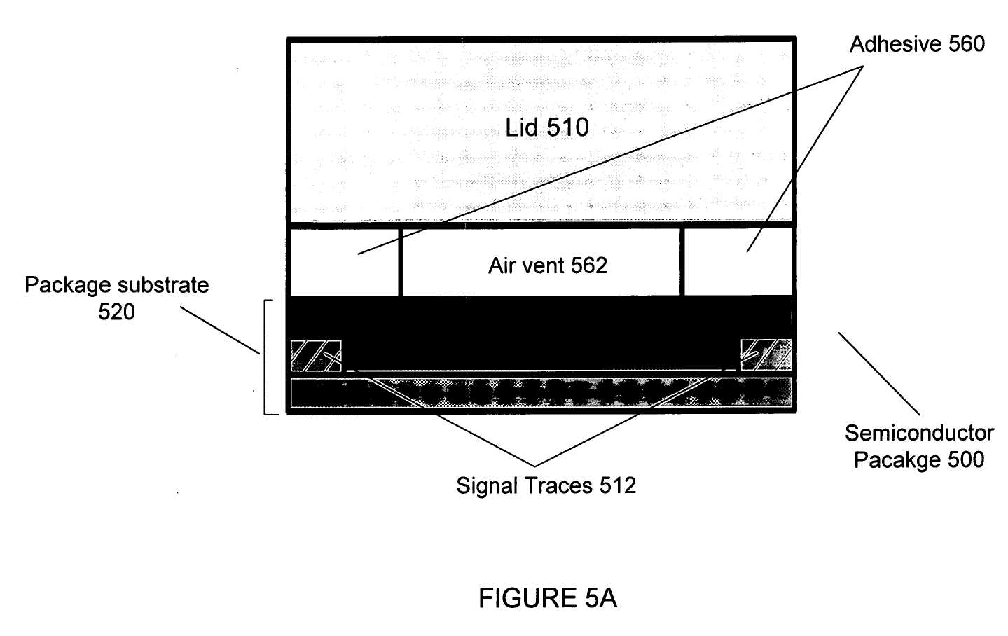

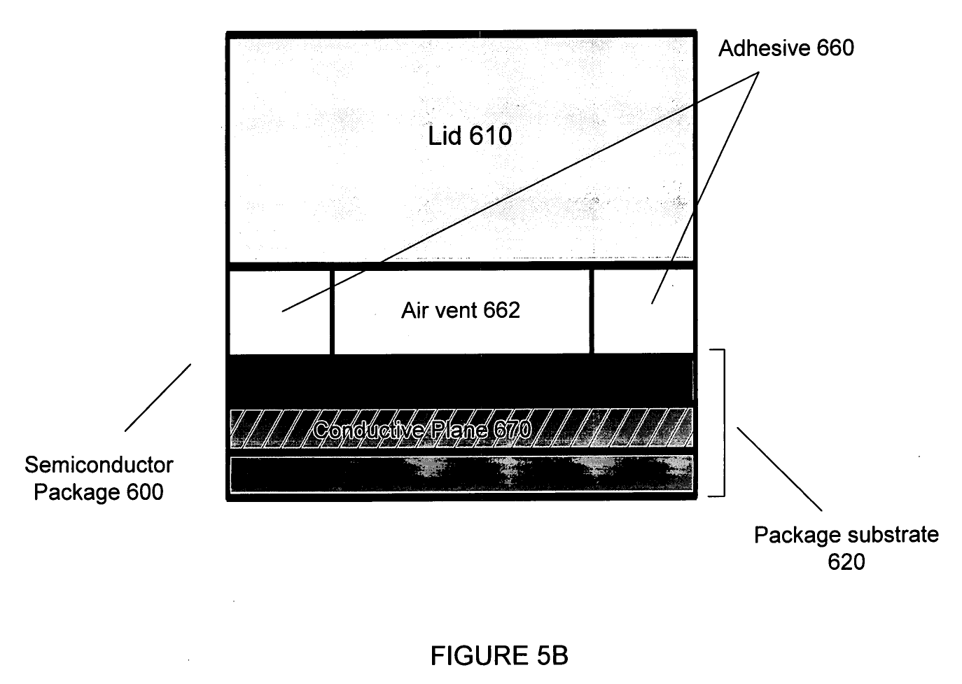

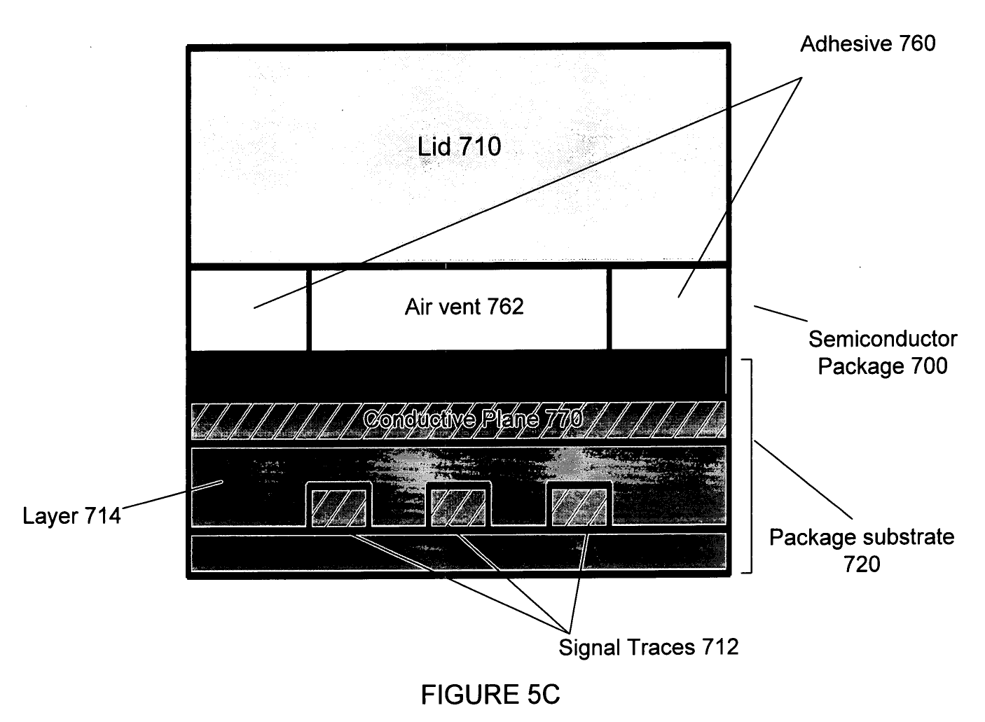

Turning to FIGS. 5A-5C, partial cross-sectional views of semiconductor packages designed according to embodiments of the present invention are depicted. FIG. 5A depicts one embodiment of an air hole vent 562 formed in the adhesive 560 on the package substrate 520 of a semiconductor package 500 where signal traces in the package are not routed underneath the air vent. Semiconductor package 500 has lid 510 which is coupled to package substrate 520 by adhesive 560. Air vent hole 562 is formed in adhesive 560. Adhesive 560 may be a film type adhesive, a liquid type adhesive or any other type of adhesive as discussed previously. Thus, air can escape from air vent hole 562 during a reflow process involving semiconductor package 500.

A set of signal traces 512 are routed on or through package substrate 520. However, no signal traces 512 are located in area 514 of package substrate 520 directly underneath air vent hole 562. In one particular embodiment because of the rough resolution of the processes which may form air vent 562 in adhesive 560, package 500 may be designed such that no signal trace 512 will be located within a tolerance area. This tolerance area may take into account the anticipated tolerance with which within air vent hole 562 can be formed, typically 100-200 microns. Thus, the tolerance area may encompass area 514 under the location of air vent hole 562 plus two resolution areas 517, 518 proximate to area 514. Each of these resolution areas 517, 518 may be approximately the size of the anticipated tolerance or resolution of the formation process by which air vent hole 562 may be formed. By designing package 500 such that no signal traces 512 are routed within this tolerance area, the tolerances of the formation process of air vent hole 562 may be taken into account such that signal traces 512 are not located under air vent hole 562. As can be seen, as signal traces 512 are not routed under air vent hole 562, air vent hole 562 does not effect the impedance of signal traces 512. Thus, the design of signal traces 512 does not have to be modified to account for air vent hole 562.

Another way to ensure that the design of signal traces does not have to be modified to account for an air vent hole is to utilize the portion of the package substrate under the air vent hole for a conductive plane (e.g. power or ground plane) intended for use with the power distribution network of the semiconductor package. FIG. 5B depicts one embodiment of an air hole vent 662 formed in the adhesive 660 on the package substrate 620 of a semiconductor package 600 where signal traces (not pictured in the partial cross sectional view of FIG. 5B) in the package are not routed directly underneath the air vent. Instead, a conductive plane is routed underneath the air vent hole. Semiconductor package 600 has lid 610 which is coupled to package substrate 620 by adhesive 660. Air vent hole 662 is formed in adhesive 660. Adhesive 660 may be a film type adhesive, a liquid type adhesive or any other type of adhesive as discussed previously. Thus, air can escape from air vent hole 662 during a reflow process involving semiconductor package 600.

Signal traces (not shown) are routed on or through package substrate 620. However, no signal traces are located under air vent hole 662. Instead, conductive plane 670 in package substrate 620 is routed underneath air vent hole 662. In one particular embodiment, conductive plane 670 is a solid power or ground plane utilized with the power distribution network of semiconductor package 600, and may pay be involved in conducting current to or from an outside source to or from the die in semiconductor package 600. By designing package 600 such that conductive plane 670 is routed under air vent hole 662, no signal traces are routed underneath air vent hole 662. Consequently, air vent hole 662 does not affect the impedance of signal traces in semiconductor package 600 and the design of signal traces in semiconductor package 600 does not have to be modified to account for air vent hole 662.

In some cases, however, the number of signal traces to be utilized in conjunction with a particular semiconductor is high enough that it is desirable to utilize the area underneath an air vent hole to route signal traces to reduce crowding of these signal traces in the resultant package. To ensure that the design of signal traces does not have to be modified to account for an air vent hole a conductive plane intended for use with the power distribution network of the semiconductor package may be placed under the air vent hole. Signal traces can then be routed under this conductive plane and under the air vent hole without the air vent hole affecting the impedance of these signal traces.

FIG. 5C depicts one embodiment of an air hole vent formed in the adhesive on the package substrate of a semiconductor package where signal traces and a conductive plane are routed underneath the air vent hole, with the conductive plane situated between the air vent hole and the signal traces. Semiconductor package 700 has lid 710 which is coupled to package substrate 720 by adhesive 760. Air vent hole 762 is formed in adhesive 760. Adhesive 760 may be a film type adhesive, a liquid type adhesive or any other type of adhesive as discussed previously. Thus, air can escape from air vent hole 762 during a reflow process involving semiconductor package 700.

Conductive plane 770 is routed underneath air vent hole 762. Signal traces 712 are routed on or through package substrate 720 underneath conductive plane 770. In one particular embodiment, signal traces 712 may be routed through layer 714 of package substrate 720 directly underneath conductive plane 770. Conductive plane 770 may be a solid power or ground plane utilized with the power distribution network of semiconductor package 700, and may be involved in conducting current to or from an outside source to or from the die in semiconductor package 700. By designing package 700 such that conductive plane 770 is routed between signal traces 712 and air vent hole 762, signal traces 712 may be routed underneath air vent hole 762 without air vent hole 762 affecting the impedance of these signal traces 712.

As can be seen, by utilizing the systems and methods of the present invention, the effect of an air vent hole on signal traces in a semiconductor package may be substantially reduced. Part and parcel with this benefit comes an additional benefit: because the affect on the impedance of signal traces underneath an air vent is reduced by the systems and methods of the present invention, an air vent may be placed practically anywhere within a particular semiconductor package.

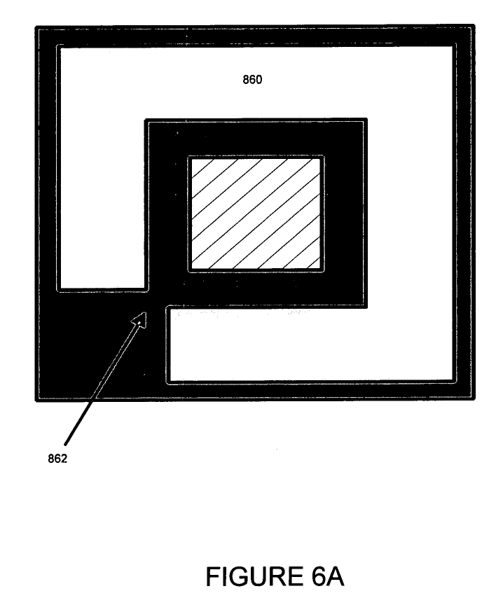

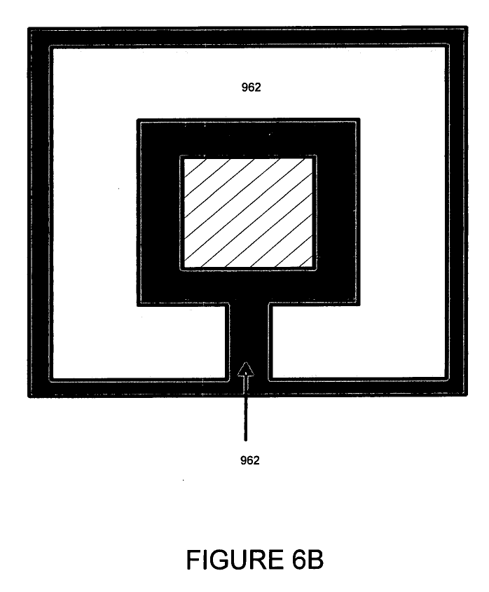

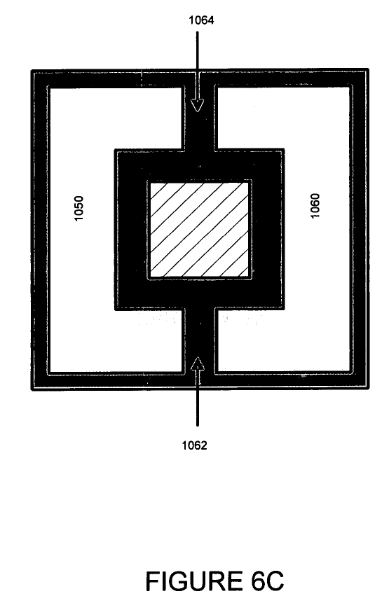

FIGS. 6A-6C illustrate embodiments of the placement of air vent holes in semiconductor packages which employ embodiments of the present invention. FIG. 6A depicts an embodiment of a semiconductor package where air vent hole 862 is formed at a corner of adhesive 860 used to attach a lid (not shown) to the semiconductor package. FIG. 6B depicts an embodiment of a semiconductor package where air vent hole 962 is formed along one side of adhesive 962 used to attach a lid (not shown) to the semiconductor package. FIG. 6C depicts an embodiment of a semiconductor package where two air vent holes 1062, 1064 are formed in adhesive 1050, 1060 used to attach a lid (not shown) on opposite sides of the semiconductor package. In one embodiment, there may be no need to separately form air vents 1062, 1064 in adhesive 1050, 1060, as adhesive 1050, 1060 may be printed, dispensed or formed onto package substrate independently as to form air vents 1062, 1064. As can be imagined from FIGS. 6A-6C an almost infinite number and placement of air vent holes may be utilized with semiconductor packages that employ embodiments of the present invention.

It will be apparent to those of skill in the art after reading this disclosure that traditional manufacturing processes may be utilized to achieve the structures and semiconductor packages disclosed herein. Including using masks, photomasks, x-ray masks, mechanical masks, oxidation masks, lithography etc to form the structures described with respect to the systems and methods of the present invention. It will also be apparent that the systems and methods disclosed for reducing the effect features on the substrate of a semiconductor package have on the impedance of signal traces may be applied no matter the feature. Furthermore, the combinations and embodiments of the systems and methods presented may be utilized no matter the type of package, signal traces or power distribution network is used. It will also be apparent that the particular embodiment of the invention to utilize in a particular case will depend on the characteristics of the case, and may include such factors as semiconductor type, frequency, or power consumption; the type and amount of adhesive being utilized, the size of the air vent hole, the type and size of the lid being utilized, the manufacturing processes etc. The particular embodiment of the invention to be utilized may be determined based on an empirical analysis or simulation involving one or more of these factors, as will be apparent to those of ordinary skill in the art.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component of any or all the claims.

What is claimed is:

1. A semiconductor package, comprising:
a substrate;
an air vent hole formed on the substrate;
a set of signal traces, wherein none of the signal traces in the set of signal traces are in an area beneath the air vent.

2. The semiconductor package of claim 1, wherein none of the signal traces are located within a tolerance area.

3. The semiconductor package of claim 2, wherein the tolerance area comprises a first resolution area proximate to the area and a second resolution area proximate to the area.

4. The semiconductor package of claim 3, wherein the first resolution area and the second resolution area are 100-200 microns.

5. The semiconductor package of claim 1, further comprising an adhesive, wherein the adhesive is on the substrate and the air vent hole is formed in the adhesive.

6. The semiconductor package of claim 5, wherein the adhesive is operable to couple a lid to the substrate, and the air vent hole is formed between the lid and the substrate.

7. The semiconductor package of claim 6, wherein the air vent hole is formed by screen printing the adhesive or dispensing the adhesive.

8. The semiconductor package of claim 1, further comprising a conductive plane, wherein the conductive plane is beneath the air vent.

9. The semiconductor package of claim 8, wherein the conductive plane is a power plane or a ground plane.

10. A semiconductor package, comprising:
a substrate;
an air vent hole formed on the substrate;
a set of signal traces, wherein at least one of the set signal traces in the set of signal traces is beneath the air vent; and
a conductive plane, wherein the conductive plane is beneath the air vent and between the at least one of the set of signal traces and the air vent.

11. The semiconductor package of claim 10, wherein the substrate comprises a set of layers, and the at least one of the set of signal traces is in a first layer of the set of layers formed directly beneath the conductive plane.

12. The semiconductor package of claim 11, further comprising an adhesive, wherein the adhesive is on the substrate and the air vent hole is formed in the adhesive.

13. The semiconductor package of claim 12, wherein the adhesive is operable to couple a lid to the substrate, and the air vent hole is formed between the lid and the substrate.

14. A method for a semiconductor package, comprising:
forming a substrate;
forming an air vent hole on the substrate;
forming a set of signal traces such that none of the signal traces in the set of signal traces are in an area beneath the air vent.

15. The method of claim 14, wherein none of the signal traces are formed within a tolerance area.

16. The method of claim 15, wherein the tolerance area comprises a first resolution area proximate to the area and a second resolution area proximate to the area.

17. The method of claim 16, wherein the first resolution area and the second resolution area are 100-200 microns.

18. The method of claim 14, further comprising placing an adhesive on the substrate, wherein the air vent hole is formed in the adhesive.

19. The method of claim 18, wherein the adhesive is operable to couple a lid to the substrate, and the air vent hole is formed between the lid and the substrate.

20. The method of claim 14, further comprising forming a conductive plane beneath the air vent.

21. A method for a semiconductor package, comprising:
forming a substrate;
forming an air vent hole on the substrate;
forming a set of signal traces, wherein at least one of the set signal traces in the set of signal traces is formed beneath the air vent; and
forming a conductive plane, wherein the conductive plane is formed beneath the air vent and between the at least one of the set of signal traces and the air vent.

22. The method of claim 21, wherein the substrate comprises a set of layers, and the at least one of the set of signal traces is in a first layer of the set of layers formed directly beneath the conductive plane.

23. The method of claim 22, further comprising placing an adhesive on the substrate, wherein the air vent hole is formed in the adhesive.

24. The method of claim 23, wherein the adhesive is operable to couple a lid to the substrate, and the air vent hole is formed between the lid and the substrate.
